(19) United States
(12) Patent Application Publication
(10) Pub. No.: US 2010/0141319 A1
(43) Pub. Date: Jun. 10, 2010

(54) CLOCK SIGNAL OUTPUT CIRCUIT

(75) Inventor: Masazumi Marutani, Kawasaki (JP)

Correspondence Address: KATTEN MUCHIN ROSENMAN LLP, 575 MADISON AVENUE, NEW YORK, NY, 10022-2585, US

(73) Assignee: FUJITSU LIMITED, Kawasaki-shi (JP)

(21) Appl. No.: 12/701,910

(22) Filed: Feb. 8, 2010

Related U.S. Application Data
(63) Continuation of application No. PCT/JP2007/067135, filed on Sep. 3, 2007.

(51) Int. Cl. H03K 5/12

(52) U.S. Cl. 327/170

(57) ABSTRACT

A clock signal output circuit includes a clock signal source which produces a clock signal, a buffer circuit which drives the clock signal while adjusting rise and fall times of the clock signal according to control signals, a rise-time frequency generator, responsive to the control signals, which produces a rise-time signal having a frequency corresponding to the rise time given by the buffer circuit, a fall-time frequency generator, responsive to the control signals, which produces a fall-time signal having a frequency corresponding to the fall time given by the buffer circuit, and a control signal generator which produces the control signals, based on the frequencies of the rise-time signal and fall-time signal.

This application is a continuing application, filed under 35 U.S.C. §111(a), of International Application PCT/JP2007/067135, filed Sep. 3, 2007.

### FIELD

The embodiments discussed herein relate to clock signal output circuits.

### BACKGROUND

Radio data communications systems, including those providing television broadcast programs and mobile phone services, have been growing in capacity with the aim of expanding services. Such systems have also seen the demand for communication services using presently available resources such as vacant frequency bands, as well as for the provision of mobility. Each electronic component constituting a terminal device therefore has a higher performance than the existing one. For example, frequency synthesizers are used in a terminal device to generate local clock frequencies for transmission and reception of signals. In addition to satisfying the simultaneous requirements of low noise figure and wide-band response, the frequency synthesizer circuit has also to be operable at a very low power consumption, capable of capturing high frequencies, and configurable with a fine frequency step size. Another example is a mixer circuit using in-phase and quadrature-phase clock signals to reduce image interference. In this circuit, the two clock signals have to be exactly 90 degrees out of phase with each other to avoid adverse effects on the signal characteristics.

In the field of electronics, the complementary metal-oxide semiconductor (CMOS) technology is widely used because of the benefit of its low power consumption. CMOS circuits use both positive-channel MOS (PMOS) and negative-channel MOS (NMOS) transistors. The output signal swings between power supply voltage and ground voltage, which correspond respectively to a high state and a low state of the digital logic level. The electrical characteristics of PMOS and NMOS transistors depend on thresholds, mobility of majority carrier (electrons or holes) and other physical parameters, as well as on the structure of devices. They may deviate, however, from the intended design as a result of variations introduced in the manufacturing process or operating environment. It is not unusual that these factors of deviation lead to a technical problem such as unequal rise time (Tr) and fall time (Tf) of a clock signal.

As an example of an existing technique of adjusting Tr and Tf to eliminate their difference, Japanese Laid-open Patent Publication No. 2001-274670 proposes a signal output circuit containing a differentiating circuit and voltage comparators (see, for example, paragraph Nos. 0036 to 0061, FIGS. 8, 9, 11, and 12). This circuit is designed to correct Tr and Tf of an output signal driving a heavy external load. For example, the proposed signal output circuit uses a differentiating circuit to sense the slope of rising and falling edges. FIG. 11 of the noted patent publication illustrates an output waveform 27 of this differentiating circuit. The differentiated signal is then subjected to voltage comparators for comparison with a pair of predetermined thresholds, so as to detect and correct the difference between Tr and Tf.

The above signal output circuit relies on the voltage-domain signal processing techniques such as differentiation and threshold comparison. However, the techniques of this type are not suitable for high-precision correction of Tr-Tf differences for the following reasons.

First, the thresholds of voltage comparators have to be selected with some amount of safety margin to prevent the operation of comparators from being disturbed by their difference in offset voltage. Accordingly, it is not possible to set a small threshold to the comparators for high-precision detection of Tr and Tf.

Second, as the conventional signal output circuit detects Tr and Tf as differentiated pulse signals, Tr and Tf may not be detected unless their corresponding pulse signals are large enough to exceed the threshold. This means that the precision of Tr and Tr adjustment is limited by the threshold value.

Third, those differentiated signals of Tr and Tf usually have very small pulse widths because of the fast transitions of the signal of interest. In an attempt to overcome the difficulty of such narrow pulse detection, the conventional signal output circuit employs pre-buffer circuits subsequent to the differentiating circuit. For example, FIG. 11 of the above-noted patent publication illustrates a pre-buffer output 29. The use of such pre-buffer circuits, however, does not fully solve the limitation on the precision of Tr and Tr detection.

### SUMMARY

According to an aspect of the invention, a clock signal output circuit includes a clock signal source which produces a clock signal, a buffer circuit which drives the clock signal while adjusting rise and fall times of the clock signal according to control signals, a rise-time frequency generator, responsive to the control signals, which produces a rise-time signal having a frequency corresponding to the rise time given by the buffer circuit, a fall-time frequency generator, responsive to the control signals, which produces a fall-time signal having a frequency corresponding to the fall time given by the buffer circuit, and a control signal generator which produces the control signals, based on the frequencies of the rise-time signal and fall-time signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 provides an overview of a clock signal output circuit according to an embodiment of the invention;

FIG. 2 is a block diagram of a clock signal output circuit according to an embodiment;

FIG. 3 is a schematic circuit diagram of a buffer circuit illustrated in FIG. 2;

FIG. 4 is a detailed block diagram of a Tr-Tf detection frequency generator and a Tr-Tf discriminator illustrated in FIG. 2;

FIG. 5 is a schematic circuit diagram of a Tr oscillator illustrated in FIG. 4;

FIG. 6 is a timing diagram depicting how the Tr oscillator of FIG. 5 operates;

FIG. 7 is a schematic circuit diagram of a Tf oscillator illustrated in FIG. 4;

FIG. 8 is a timing diagram depicting how the Tf oscillator of FIG. 7 operates;

FIG. 9 is a schematic circuit diagram of a frequency comparator illustrated in FIG. 4;

FIG. 10 is a timing diagram depicting how D flip-flops operate in the circuit of FIG. 9;

FIG. 11 is a schematic circuit diagram of a control signal generator illustrated in FIG. 4;

FIGS. 12A to 12C depict how the decoder works in the circuit of FIG. 11;

FIG. 13 illustrates an example circuit with a high-sensitivity buffer circuit added after a buffer circuit;

FIG. 14 illustrates output waveforms of the circuit of FIG. 13;

FIG. 15 illustrates an example circuit which provides a clock signal to an IQ-phase divider through a buffer circuit;

FIG. 16 illustrates output waveforms of the circuit of FIG. 15; and

FIG. 17 illustrates an example circuit in which the clock signal output circuit of FIG. 2 is used together with an IQ-phase divider.

### DESCRIPTION OF EMBODIMENTS

Embodiments of the present invention will now be described below with reference to the accompanying drawings, wherein like reference numerals refer to like elements throughout.

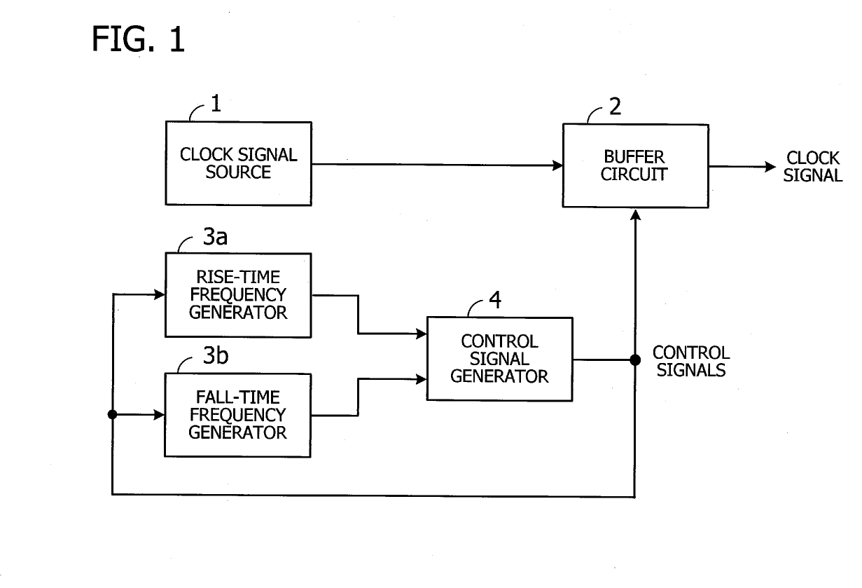

FIG. 1 provides an overview of a clock signal output circuit according to an embodiment of the present invention. As can be seen from FIG. 1, the clock signal output circuit includes a clock signal source 1, a buffer circuit 2, a rise-time frequency generator 3a, a fall-time frequency generator 3b, and a control signal generator 4.

The clock signal source 1 provides a clock signal with a duty ratio of, for example, 50%. The buffer circuit 2 is designed to reshape this clock signal by adjusting its rising and falling times according to given control signals. For example, the buffer circuit 2 reduces the rise time of the clock signal according to control signals in the case where the clock signal has a longer rise time than its fall time.

The rise-time frequency generator 3a, responsive to control signals, produces a rise-time signal having a frequency corresponding to the rise time given by the buffer circuit 2. When, for example, the buffer circuit 2 reduces the rise time of the clock signal according to given control signals, the rise-time frequency generator 3a also responds to those control signals by producing a rise-time signal having a frequency corresponding to the reduced rise time at the buffer circuit 2. That is, the rise-time frequency generator 3a converts the rise time of the buffer output into a frequency signal.

The fall-time frequency generator 3b, responsive to control signals, produces a fall-time signal having a frequency corresponding to the fall time given by the buffer circuit 2. When, for example, the buffer circuit 2 reduces the fall time of the clock signal according to given control signals, the fall-time frequency generator 3b also responds to those control signals by producing a fall-time signal having a frequency corresponding to the reduced fall time at the buffer circuit 2. That is, the fall-time frequency generator 3b converts the fall time of the buffer output into a frequency signal.

The control signal generator 4 produces control signals based on the frequencies of the rise-time signal and fall-time signal provided by the rise-time frequency generator 3a and fall-time frequency generator 3b, respectively. The produced control signals are supplied to the buffer circuit 2, rise-time frequency generator 3a, and fall-time frequency generator 3b. For example, the control signal generator 4 produces control signals that will lower the fall-time signal frequency in the case where the rise-time signal has a higher frequency than the fall-time signal. The buffer circuit 2 shapes the clock signal according to those control signals so as to equalize its rise time and fall time.

The clock signal output circuit according to the above embodiment adjusts rise and fall times of a clock signal in its buffer circuit 2. For this purpose, the proposed circuit converts the rise and fall times into frequency signals, thus enabling more precise shaping of the clock signal waveform.

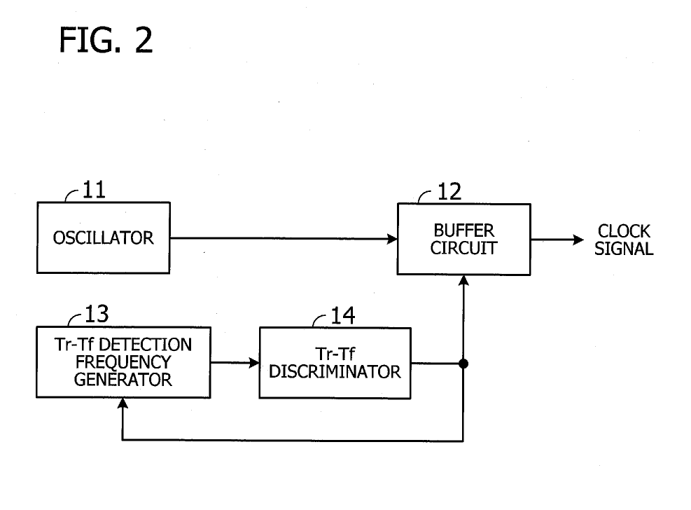

Referring now to the block diagram of FIG. 2, an embodiment of a clock signal output circuit will be described below. As can be seen from FIG. 2, this clock signal output circuit is formed from an oscillator 11, a buffer circuit 12, a Tr-Tf detection frequency generator 13, and a Tr-Tf discriminator 14. The illustrated clock signal output circuit may be implemented in a single semiconductor chip and used to provide subsequent electronic circuits with a clock signal whose rise time (Tr) and fall time (Tf) are adjusted to have equal values.

The oscillator 11 produces a clock signal with a duty ratio of, for example, 50% and supplies the produced clock signal to the buffer circuit 12. The buffer circuit 12 has a higher drive capability than the oscillator 11 to drive subsequent electronic circuits (not depicted) with the clock signal produced by the oscillator 11. The buffer circuit 12 is designed to vary Tr and Tf of a given clock signal under the control of the Tr-Tf discriminator 14.

The Tr-Tf detection frequency generator 13 contains transistors having the same characteristics as those used in the buffer circuit 12 to drive the clock signal. The use of such transistors permits the Tr-Tf detection frequency generator 13 to detect Tr and Tf of the clock signal in the buffer circuit 12. That is, the clock signal may vary in its Tr and Tf in the buffer circuit 12. The Tr-Tf detection frequency generator 13 is responsive to such a variation when it occurs. The Tr-Tf detection frequency generator 13 converts the detected Tr and Tf into frequency signals (i.e., signals with frequencies corresponding to Tr and Tf) and supplies them to the Tr-Tf discriminator 14.

Based on the frequency signals supplied from the Tr-Tf detection frequency generator 13, the Tr-Tf discriminator 14 produces control signals to adjust Tr and Tf in the buffer circuit 12. The control signals produced by the Tr-Tf discriminator 14 are also fed back to the Tr-Tf detection frequency generator 13. According to these control signals, the Tr-Tf detection frequency generator 13 adjusts Tr and Tf, just as done in the buffer circuit 12, thus outputting frequency signals corresponding to the adjusted Tr and Tf.

What the Tr-Tf detection frequency generator 13 observes as its Tr and Tf are equivalent to those that are actually produced in the buffer circuit 12. The Tr-Tf detection frequency generator 13 produces frequency signals corresponding to such Tr and Tf, and based on those frequency signals, the Tr-Tf discriminator 14 makes adjustments so that Tr and Tf will match with each other in the buffer circuit 12 and Tr-Tf detection frequency generator 13. The proposed clock signal output circuit may thus produce a clock signal with equal Tr and Tf.

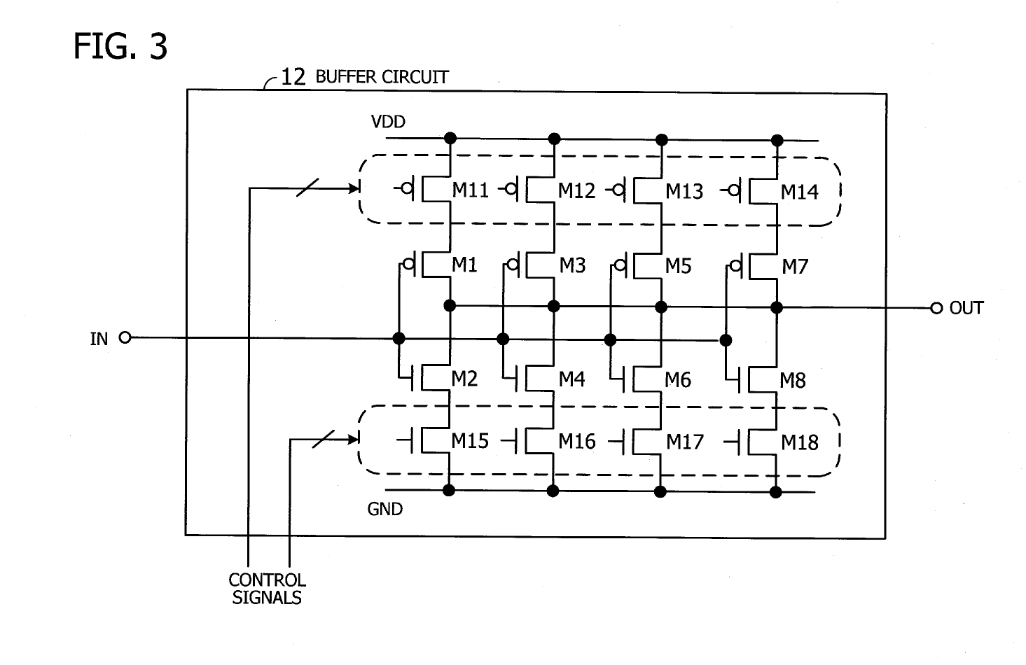

FIG. 3 is a schematic diagram of the buffer circuit 12 illustrated in FIG. 2. As can be seen from FIG. 3, this buffer circuit 12 is formed from PMOS transistors M1, M3, M5, M7, and M11-M14, and NMOS transistors M2, M4, M6, M8, and M15-M18. The buffer circuit 12 receives a clock signal from the oscillator 11 at its input terminal IN and sends out a clock signal with adjusted Tr and Tf from its output terminal OUT.

Transistors M1 and M2 form an inverter, as do the other complementary pairs of transistors M3 and M4, M5 and M6, and M7 and M8. The inputs of all those inverters are commonly connected to the input terminal IN to receive a clock signal from the oscillator 11, while their outputs are wired together to the output terminal OUT.

PMOS transistors M11, M12, M13, and M14 are inserted between the power supply voltage VDD and the sources of transistors M1, M3, M5, and M7 constituting the above-noted inverters. The gates of those transistors M11-M14 are driven individually by a plurality of control signals supplied from the Tr-Tf discriminator 14. There are as many control signal lines as the number of such PMOS transistors. For example, the buffer circuit 12 of FIG. 3 uses four such signals to control the individual state of four PMOS transistors M1, M3, M5, and M7.

NMOS transistors M15, M16, M17, and M18 are placed between the ground voltage GND and the sources of transistors M2, M4, M6, and M8 constituting the above-noted inverters. The gates of those transistors M15-M18 are driven individually by a plurality of control signals supplied from the Tr-Tf discriminator 14. There are as many control signal lines as the number of those NMOS transistors. For example, the buffer circuit 12 of FIG. 3 uses four such signals to control the individual state of four NMOS transistors M2, M4, M6, and M8.

The buffer circuit 12 is designed to adjust Tr and Tf of its clock signal output by controlling the on-off state of transistors M11-M18. For example, by activating more of the transistors M11-M14, more connections will proportionally be produced between the sources of transistors M1, M3, M5, and M7 and the power supply voltage VDD. This enables the buffer circuit 12 to supply more current to the clock signal line when the signal goes high, thus reducing Tr of that transition. In turn, the number of connections between the sources of transistors M1, M3, M5, and M7 and the power supply voltage VDD is reduced by deactivating more of the transistors M11-M14. This results in an increased Tr of the clock signal output.

Similarly to the above, activating more of the transistors M15-M18 will yield a proportional increase of active connections between the sources of transistors M2, M4, M6, and M8 and the ground voltage GND. This enables the buffer circuit 12 to sink more current when the clock signal output goes low, thus reducing Tf of that transition. In turn, the number of connections between the sources of transistors M2, M4, M6, and M8 and the ground voltage GND is reduced by deactivating more of the transistors M15-M18. This results in an increased Tf of the clock signal output.

As can be seen from the above, the buffer circuit 12 is configured to turn on and off the transistors M11-18 according to control signals. By doing so, the buffer circuit 12 varies the amount of current flowing from power supply voltage VDD to the inverters circuits or from the inverters circuits to ground GND, thus tuning Tr and Tf of the output signal.

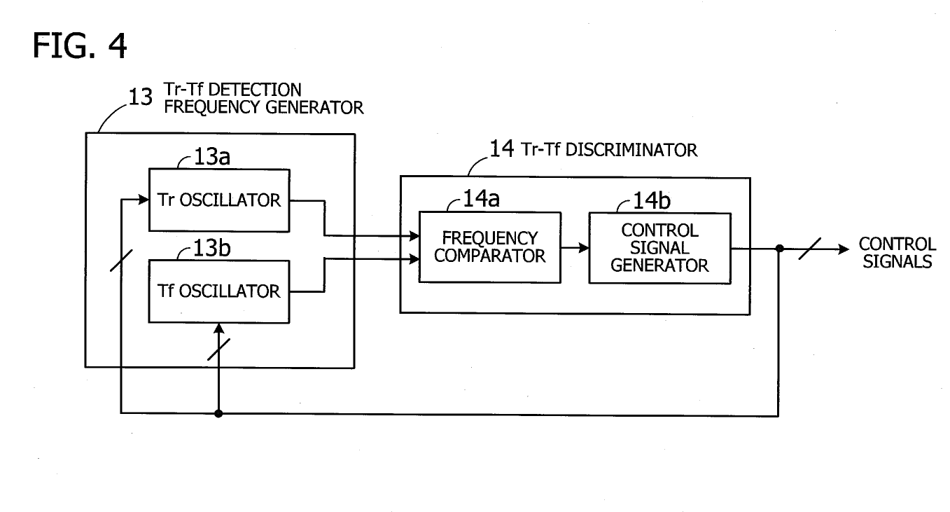

FIG. 4 is a detailed block diagram of the Tr-Tf detection frequency generator 13 and Tr-Tf discriminator 14 illustrated in FIG. 2. As FIG. 4 illustrates, the Tr-Tf detection frequency generator 13 includes a Tr oscillator 13a and a Tf oscillator 13b, while the Tr-Tf discriminator includes a frequency comparator 14a and a control signal generator 14b.

The Tr oscillator 13a oscillates with a cycle period determined by Tr of the clock signal. The Tr oscillator 13a is formed from transistors having the similar characteristics as the transistors M1, M3, M5, and M7 constituting inverters in the foregoing buffer circuit 12, so as to detect Tr of the buffer circuit 12 and convert it to a frequency signal. Similarly to the buffer circuit 12, the Tr oscillator 13a is also supplied with control signals from the Tr-Tf discriminator 14. Based on those control signals, the Tr oscillator 13a detects Tr equivalent to what is adjusted in the buffer circuit 12.

The Tf oscillator 13b oscillates with a cycle period determined by Tf of the clock signal. The Tf oscillator 13b is formed from transistors having the similar characteristics as the transistors M2, M4, M6, and M8 constituting inverters in the foregoing buffer circuit 12, so as to detect Tf of the buffer circuit 12 and convert it to a frequency signal. Similarly to the buffer circuit 12, the Tf oscillator 13b is also supplied with control signals from the Tr-Tf discriminator 14. Based on those control signals, the Tf oscillator 13b detects Tf equivalent to what is adjusted in the buffer circuit 12.

The frequency comparator 14a compares two signals received from the Tr oscillator 13a and Tf oscillator 13b in terms of their frequencies. The frequency comparator 14a supplies the comparison result to the control signal generator 14b in the form of, for example, a voltage signal. This frequency comparator 14a may be implemented as a phase frequency comparator generally used in phase-locked loop (PLL) circuits.

The control signal generator 14b produces control signals based on the result of a frequency comparison performed by the frequency comparator 14a. If, for example, the frequency signal of Tr has a higher frequency than that of Tf, the Tr-Tf discriminator 14 supplies the buffer circuit 12, Tr oscillator 13a, and Tf oscillator 13b with control signals that will reduce the frequency of the former frequency signal, thereby equalizing Tr and Tf of the clock signal.

As can be seen from the above description, the clock signal output circuit employs a Tr-Tf detection frequency generator 13 to convert Tr and Tf into frequency signals and a frequency comparator 14a to compare Tr with Tf in a digital fashion. Accordingly, the proposed clock signal output circuit achieves accurate adjustment of Tr and Tf, without the need for considering the effect of offset or noise when detecting imbalance between Tr and Tf, which the conventional analog approach has to deal with.

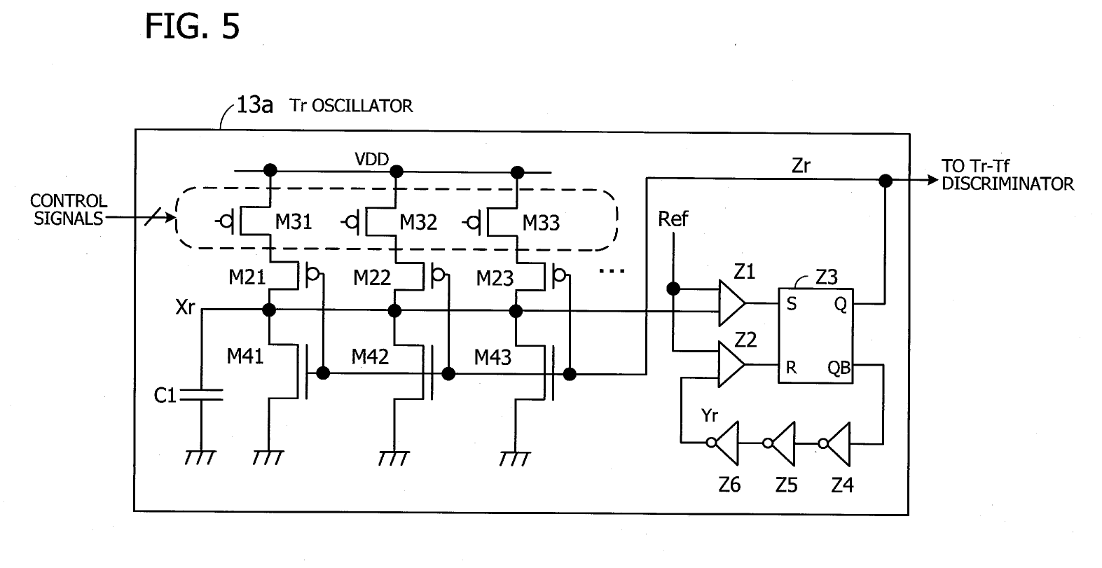

FIG. 5 is a schematic circuit diagram of the Tr oscillator 13a illustrated in FIG. 4. As seen in FIG. 5, the Tr oscillator 13a is formed from PMOS transistors M21-M23 and M31-M33, NMOS transistors M41-M43, comparators Z1 and Z2, an RS flip-flop Z3, and delay circuits Z4-Z6.

Transistors M21-M23 have the similar characteristics as transistors M1, M3, M5, and M7 used in the buffer circuit 12 of FIG. 3. For example, the transistors M21-M23 are fabricated with the similar gate length and width as the transistors M1, M3, M5, and M7 so as to provide the similar current drivability. While FIG. 5 only depicts three transistors M21-M23 on their row, the Tr oscillator 13a actually contains as many such transistors as the number of transistors constituting inverters in the buffer circuit 12. In the present example, the Tr oscillator 13a actually contains four such transistors M21, M22, M23, and M24 (not depicted) corresponding to four transistors M1, M3, M5, and M7 in the buffer circuit 12.

Inserted between the sources of transistors M21-M23 and the power supply voltage VDD are transistors M31-M33. These transistors M31-M33 correspond to transistors M11-M14 in the buffer circuit 12. For example, the gates of transistors M31-M33 are driven by the similar set of control signals as used to drive their corresponding transistors M11-M14 in the buffer circuit 12. This means, for example, that transistor M31 turns on when its counterpart M11 in the buffer circuit 12 turns on as a result of assertion of their shared control signal.

Similarly, transistors M31 and M32 turn on when their respective counterparts M11 and M12 in the buffer circuit turn on as a result of assertion of their shared control signals.

The drains of transistors M21-M23 are connected to a capacitor C1, as are the drains of transistors M41-M43. When transistors M31-M33 turn on, the capacitor C1 is charged up through transistors M21-M23. As noted above, transistors M21-M23 have the similar characteristics as transistors M1, M3, M5, and M7 in the buffer circuit 12, and transistors M31-M33 turn on, together with the corresponding transistors M11-M14 in the buffer circuit 12 according to their shared control signals. Accordingly, the voltage across the capacitor C1 rises at the rate proportional to Tr of the buffer circuit 12 until transistors M41-M43 are activated to release the charge.

The voltage of capacitor C1 is brought to an input of a comparator Z1. The comparator Z1 compares the received voltage with a reference voltage Ref and produces a high-state signal when the received voltage exceeds the reference voltage Ref. The produced high-state signal triggers S input of an RS flip-flop Z3, causing the RS flip-flop Z3 to set its Q output to a high state. That is, the RS flip-flop Z3 produces a high-state signal at its Q output terminal when the voltage of capacitor C1 reaches the reference voltage Ref. This high-state signal forces transistors M21-M23 to an off state, while turning on transistors M41-M43 to discharge the capacitor C1.

QB output of the RS flip-flop Z3 provides an inverted version of the Q output signal. That is, a low-state signal appears at the QB output when a high-state signal is present at the Q output. This low-state signal propagates through delay circuits Z4-Z6 and reaches another comparator Z2. In the example of FIG. 5, the delay circuits Z4-Z6 are implemented as an odd number of series inverters to deliver an inverted version of QB output to the comparator Z2.

The comparator Z2 compares the output voltage of the last delay circuit Z6 with the reference voltage Ref and provides a high-state signal to R input of the RS flip-flop Z3 when the output voltage exceeds the reference voltage Ref. Accordingly, the RS flip-flop Z3 maintains the high state of its Q output until a lapse of delay time of the delay circuits Z4-Z6, and then it resets Q output back to a low state. This low-state Q output turns transistors M21-M23 on and transistors M41-M43 off, thus permitting the capacitor C1 to accumulate again the electric charge.

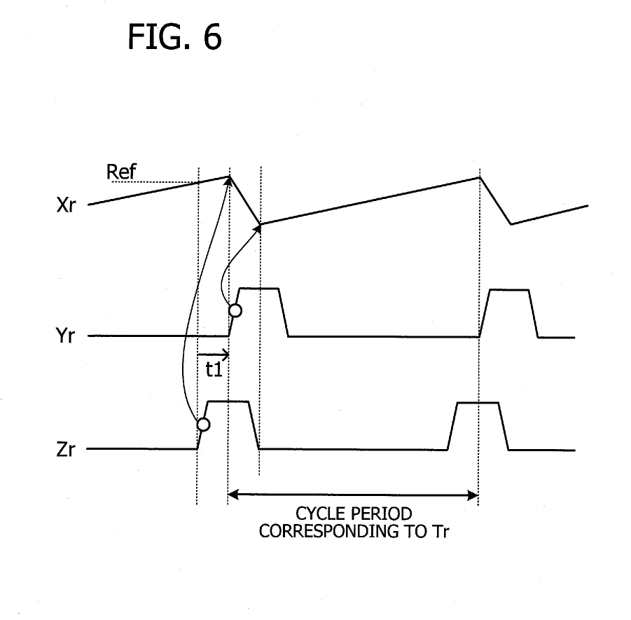

FIG. 6 is a timing diagram depicting how the Tr oscillator 13a of FIG. 5 operates. For example, FIG. 6 depicts voltages observed at points Xr, Yr, and Zr in FIG. 5. As can be seen in FIG. 6, the voltage at point Xr goes up as the capacitor C1 is charged. The increase rate of this Xr voltage depends on how many transistors M31-M33 are turned on by the control signals, as well as on the current drivability of transistors M21-M23. In other words, the increase rate of the Xr voltage represents the current drivability of transistors M1, M3, M5, and M7 in the buffer circuit 12.

When the Xr voltage reaches a reference voltage Ref, the comparator Z1 produces a high-state signal, which causes the RS flip-flop Z3 to set its Q output to a high state, as can be seen from the waveform of point Zr in FIG. 6. The low-to-high transition at point Zr turns transistors M21-M23 off and transistors M41-M43 on, thus discharging the capacitor C1. Accordingly, the voltage at point Xr goes down as seen in FIG. 6.

The RS flip-flop Z3, on the other hand, outputs a low-state signal from its QB output terminal, complementary to the high-state signal at the Q output terminal. This low-state signal is delayed and inverted by the delay circuits Z4-Z6, thus reaching the comparator Z2 in the form of a high-state signal. Accordingly, the voltage at point Yr rises to a high state with a delay of t1 after the low-to-high transition at point Zr.

The high-state signal at point Yr resets Q output of the RS flip-flop Z3 to a low state, which turns transistors M21-M23 on, and transistors M41-M43 off. The capacitor C1 begins to charge up again, and the voltage at point Xr increases gradually as a result of a current flowing into the capacitor C1 through transistors M21-M23. In other words, the capacitor C1 acts as an integrator circuit that integrates the currents flowing through transistors M21-M23.

The charge cycle of capacitor C1 depends on the current drivability of transistors M21-M23, which are selected by transistors M31-M33. In other words, the cycle period of signals appearing at points Xr, Yr, and Zr corresponds to Tr of the buffer circuit 12. Accordingly, the Tr oscillator 13a produces a signal with a frequency representing Tr.

It is noted that the Tr oscillator 13a of FIG. 5 includes comparators Z1 and Z2 to ensure that the RS flip-flop Z3 receives trigger signals that clearly distinguish between high and low states. These comparators Z1 and Z2 may therefore be eliminated in the case where the RS flip-flop Z3 has the capability of distinguishing high and low states definitely. The comparators Z1 and Z2, when employed, may preferably be configured to operate with a reference voltage Ref that is set to half the power supply voltage.

Also, for the purpose of discharging capacitor C1, transistors M41-M43 may preferably be selected from those having higher current drivabilities. For example, it is preferable that transistors M41-M43 have a large gate width and a small gate length, so as to complete discharging of capacitor C1 in a short time. With this design of transistor M41-M43, the cycle period of signals appearing at points Xr, Yr, and Zr is determined substantially by the charge time alone (where the discharge time is negligibly small).

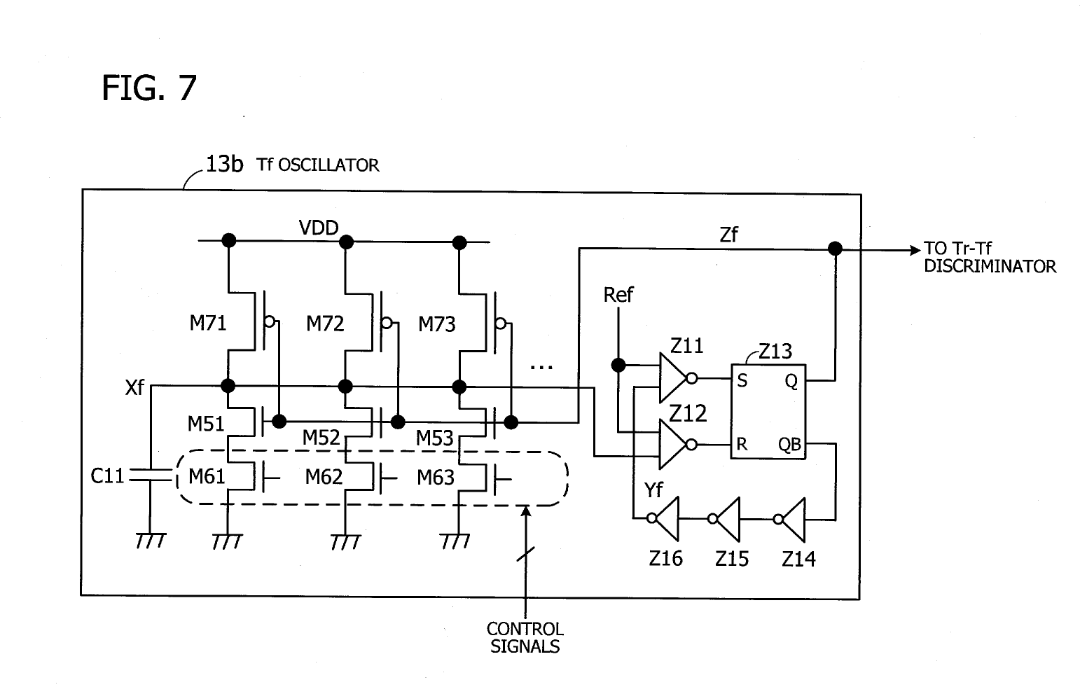

FIG. 7 is a schematic circuit diagram of the Tf oscillator 13b illustrated in FIG. 4. As seen in FIG. 7, this Tf oscillator 13b is formed from NMOS transistors M51-M53 and M61-M63, PMOS transistors M71-M73, comparators Z11 and Z12, an RS flip-flop Z13, and delay circuits Z14-Z16.

Transistors M51-M53 have the similar characteristics as transistors M2, M4, M6, and M8 used in the buffer circuit 12 of FIG. 3. For example, the transistors M51-M53 are fabricated with the similar gate length and width as the transistors M2, M4, M6, and M8 so as to provide the similar current drivability. While FIG. 7 only depicts three transistors M51-M53 on their row, the Tf oscillator 13b actually contains as many such transistors as the number of transistors constituting inverters in the buffer circuit 12. In the present example, the Tf oscillator 13b actually contains four such transistors M51, M52, M53, and M54 (not depicted) corresponding to four transistors M2, M4, M6, and M8 in the buffer circuit 12.

Inserted between the sources of transistors M51-M53 and the ground GND are transistors M61-M63. These transistors M61-M63 correspond to transistors M15-M18 in the buffer circuit 12. For example, the gates of transistors M61-M63 are driven by the similar set of control signals as used to drive their corresponding transistors M15-M18 in the buffer circuit 12. This means, for example, that transistor M61 turns on when its counterpart M15 in the buffer circuit 12 turns on as a result of assertion of their shared control signal. Similarly, transistors M61 and M62 turn on when their respective counterparts M15 and M16 in the buffer circuit turn on as a result of assertion of their shared control signals.

The drains of transistors M51-M53 are connected to a capacitor C11, as are the drains of transistors M71-M73. When transistors M61-M63 turn on, the capacitor C11 is discharged through transistors M51-M53. As noted above, transistors M51-M53 have the similar characteristics as transistors M2, M4, M6, and M8 in the buffer circuit 12, and transistors M61-M63 turn on together with the corresponding transistors M15-M18 in the buffer circuit 12 according to their shared control signals. Accordingly, the voltage across the capacitor C11 falls at the rate proportional to Tf of the buffer circuit 12 until transistors M71-M73 are activated to begin charging.

The voltage of capacitor C11 is brought to an input of a comparator Z12. The comparator Z12 compares the received voltage with a reference voltage Ref and produces a high-state signal when the received voltage falls below the reference voltage Ref. The produced high-state signal triggers R input of an RS flip-flop Z13, causing the RS flip-flop Z13 to set its Q output to a low state. That is, the RS flip-flop Z13 produces a low-state signal at its Q output terminal when the voltage of capacitor C11 falls below the reference voltage Ref. This low-state signal forces transistors M51-M53 to an off state, while turning on transistors M71-M73 to charge up the capacitor C11.

QB output of the RS flip-flop Z13 provides an inverted version of the Q-output signal. That is, a high-state signal appears at the QB output when a low-state signal is present at the Q output. The high-state signal propagates through delay circuits Z14-Z16 and reaches another comparator Z11. In the example of FIG. 7, the delay circuits Z14-Z16 are implemented as an odd number of inverters to deliver an inverted version of QB output to the comparator Z11.

The comparator Z11 compares the output voltage of the last delay circuit Z16 with the reference voltage Ref and provides a high-state signal to S input of the RS flip-flop Z13 when the output voltage falls below the reference voltage Ref. Accordingly, the RS flip-flop Z13 maintains the low state of its Q output until a lapse of a delay time given by the delay circuit Z14-Z16, and then it sets its Q output to a high state. This high-state Q output turns transistors M51-M53 on and transistors M71-M73 off, thus permitting the capacitor C11 to release again the electric charge through transistors M51-M53 and M61-M63.

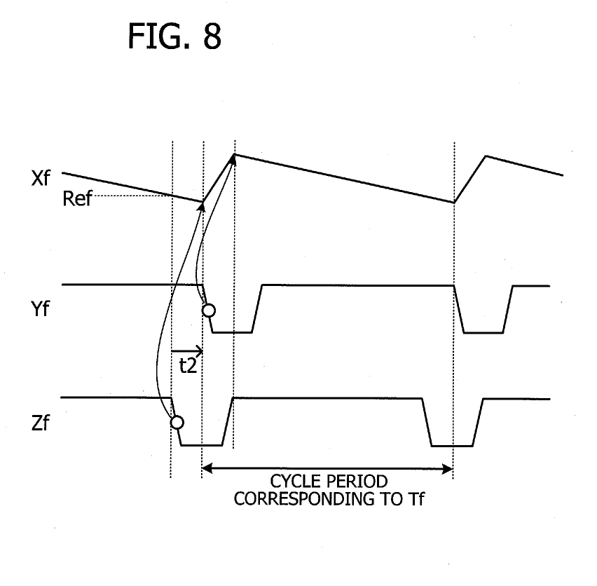

FIG. 8 is a timing diagram depicting how the Tf oscillator 13b of FIG. 7 operates. For example, FIG. 8 depicts voltages at points Xf, Yf, and Zf indicated in FIG. 7. As can be seen in FIG. 8, the voltage at point Xf goes down as the capacitor C11 is discharged. The decrease rate of this Xf voltage depends on how many transistors M61-M63 are turned on by the control signals, as well as on the current drivability of the transistors M51-M53. In other words, the decrease rate of the Xf voltage represents the current drivability of transistors M2, M4, M6, and M8 in the buffer circuit 12.

When the Xf voltage falls below a reference voltage Ref, the comparator Z12 produces a high-state signal, which causes the RS flip-flop Z13 to reset its Q output to a low state, as can be seen from the voltage curve of point Zf in FIG. 8. The high-to-low transition at point Zf turns transistors M51-M53 off and transistors M71-M73 on, thus charging up the capacitor C11. Accordingly, the voltage at point Xf goes up again as seen in FIG. 8.

The RS flip-flop Z13, on the other hand, outputs a high-state signal from its QB output terminal, complementary to the low-state signal at the Q output terminal. This low-state signal is delayed and inverted by the delay circuits Z14-Z16, thus reaching the comparator Z11 in the form of a low-state signal. Accordingly, the voltage at point Yf falls to a low state with a delay of t2 after the high-to-low transition at point Zf.

With the low-state signal at point Yf, the comparator Z11 produces a high-state signal, which causes the RS flip-flop Z13 to set its Q output to a high state. This high-state signal turns transistors M51-M53 on, and transistors M71-M73 off, thus allowing the capacitor C11 to begin discharging again. The voltage at point Xf decreases gradually as a result of the current flowing out of the capacitor C11 through transistors M51-M53. In other words, the capacitor C11 acts as an integrator circuit that integrates the currents flowing through transistors M21-M23.

The discharge cycle of capacitor C11 depends on the current drivability of transistors M51-M53, which are selected by transistors M61-M63. In other words, the cycle period of signals appearing at points Xf, Yf, and Zf corresponds to Tf of the buffer circuit 12. Accordingly, the Tf oscillator 13b produces a signal with a frequency representing Tf.

It is noted that the Tf oscillator 13b of FIG. 7 includes comparators Z11 and Z12 to ensure that the RS flip-flop Z13 receives trigger signals that clearly distinguish between high and low states. These comparators Z11 and Z12 may therefore be eliminated in the case where the RS flip-flop Z13 has the capability of distinguishing high and low states definitely. The comparators Z11 and Z12, when employed, may preferably be configured to operate with a reference voltage Ref that is set to half the power supply voltage.

Also, for the purpose of charging the capacitor C11, transistors M71-M73 may preferably be selected from those having higher current drivabilities. For example, it is preferable that transistors M71-M47 have a large gate width and a small gate length, so as to complete charging of capacitor C11 in a short time. With this design of transistor M71-M73, the cycle period of signals appearing at points Xf, Yf, and Zf is determined substantially by the discharge time alone (where the charge time is negligibly small).

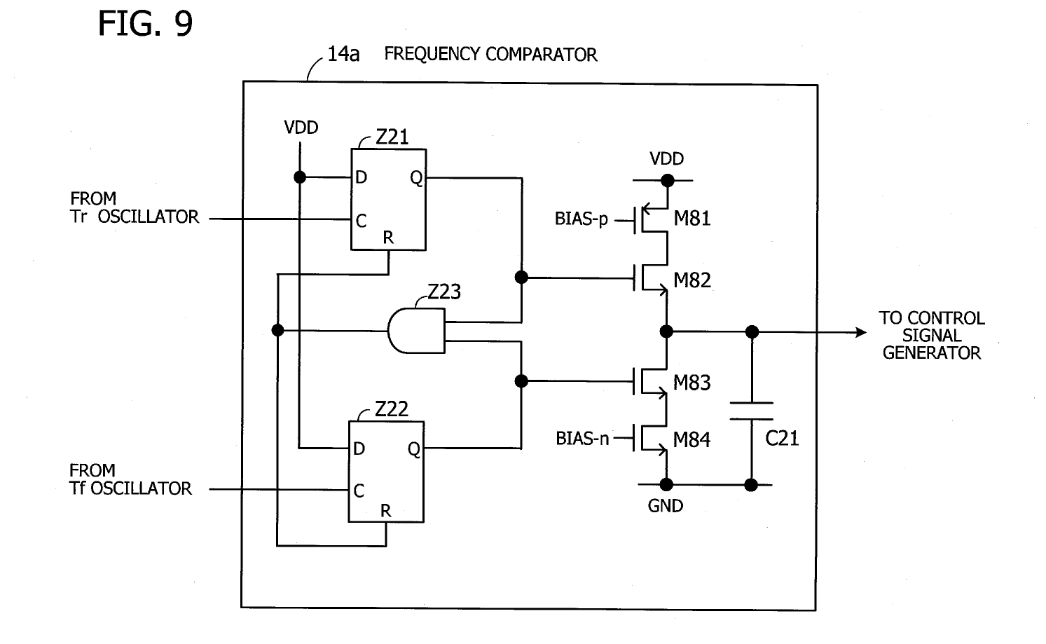

FIG. 9 is a schematic circuit diagram of the frequency comparator 14a illustrated in FIG. 4. As can be seen from FIG. 9, this frequency comparator 14a is formed from D flip-flops Z21 and Z22, an AND gate Z23, PMOS transistor M81, NMOS transistors M82, M83 and M84, and a capacitor C21.

One D flip-flop Z21 receives as its C input a frequency signal from the Tr oscillator 13a. The other D flip-flop Z22 receives as its C input a frequency signal from the Tf oscillator 13b. D inputs of the two D flip-flops Z21 and Z22 are pulled up to the power supply voltage VDD to give them a high state. Q outputs of the D flip-flops Z21 and Z22 are ANDed together by an AND gate Z23 to drive R inputs of the same.

Suppose now that Q outputs of D flip-flops Z21 and Z22 are both at a low state. When there is a low-to-high transition in the frequency signal from the Tr oscillator 13a, the corresponding D flip-flop Z21 sets its Q output to a high state. The D flip-flop Z21 will not change its Q output even if it receives more pulses of the similar frequency signal. When there is a low-to-high transition in the other frequency signal produced by the Tf oscillator 13b, the AND gate Z23 asserts its output to a high state, thus resetting both D flip-flops Z21 and Z22.

Similarly to the above, when the Q outputs of D flip-flops Z21 and Z22 are both at a low state, the Tf oscillator 13b may give a low-to-high transition with its frequency signal. This signal transition causes the D flip-flop Z22 to set its Q output to a high state. The D flip-flop Z22 will not change its Q output even if it receives more pulses of the similar frequency signal. When there is a low-to-high transition in the other frequency signal produced by the Tr oscillator 13a, the AND gate Z23 asserts its output to a high state, thus resetting the two D flip-flops Z21 and Z22. As a result of the above operation of the D flip-flops Z21 and Z22 and AND gate Z23, the difference of frequencies between the Tr oscillator 13a and Tf oscillator 13b appears at the Q outputs of the D flip-flops Z21 and Z22.

The Q output of one D flip-flop Z21 is wired to the gate of a transistor M82, while that of the other D flip-flop Z22 is wired to the gate of a transistor M83. The drains of these transistors M82 and M83 are wired together to a capacitor C21. Transistors M81 and M84, placed in series with the transistors M82 and M83, respectively, are always turned on by their bias voltages Bias-p and Bias-n when the function of frequency comparator is enabled. Transistors M81 and M84 may be turned off when frequency comparison may not be necessary.

Transistors M82 and M83 turn on and off according to the state of Q outputs of the D flip-flops Z21 and Z22, thus charging and discharging the capacitor C21. This operation of the frequency comparator 14a makes it possible to extract the difference of frequencies between the Tr oscillator 13a and Tf oscillator 13b in voltage form (i.e., high state and low state).

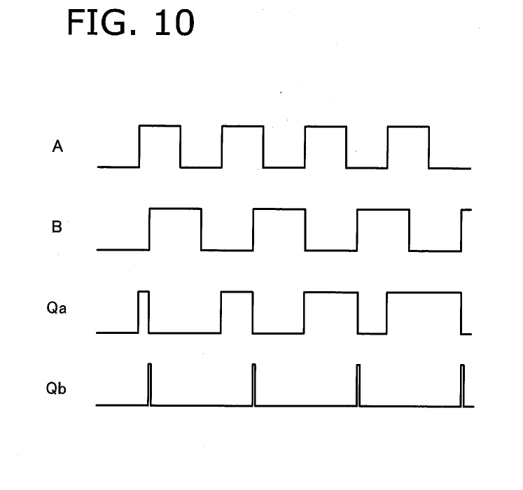

FIG. 10 is a timing diagram depicting how the D flip-flops operate in the circuit of FIG. 9. Part A of FIG. 10 illustrates a waveform of a signal that the D flip-flop Z21 (FIG. 9) receives at its C input (i.e., frequency signal supplied from the Tr oscillator 13a). Part B of FIG. 10 illustrates a waveform of a signal that the D flip-flop Z22 (FIG. 9) receives at its C input (i.e., frequency signal supplied from the Tf oscillator 13b). Part Qa of FIG. 10 illustrates a Q output waveform of the D flip-flop Z21. Part Qb of FIG. 10 illustrates a Q output waveform of the D flip-flop Z22.

The timing diagram of FIG. 10, as a whole, depicts a situation where the Tr oscillator 13a generates a frequency ωa that is higher than a frequency ωb of the Tf oscillator 13b. As ωa>ωb, the D flip-flop Z21 produces at its Q output a signal illustrated in part Qa of FIG. 10. The D flip-flop Z22, on the other hand, produces a pulse signal at its Q output, where the high-level duration is a sum of a propagation delay time of the AND gate Z23 and a reset delay time of the D flip-flops Z21 and Z22.

The capacitor C21 illustrated in FIG. 9 averages the Qa and Qb outputs depicted in FIG. 10. Since Qa has longer high-state duration than Qb in the example waveform illustrated in FIG. 10, the capacitor C21 is charged up.

In the case of ωb>ωa, the waveforms illustrated in parts Qa and Qb of FIG. 10 will be replaced with each other. That is, Qb has longer high-state duration than Qa, and accordingly, the capacitor C21 is discharged. This operation enables the frequency comparator 14a to supply the control signal generator 14b with a signal having either a high state or a low state to indicate a comparison result of frequencies between the Tr oscillator 13a and Tf oscillator 13b. For example, the control signal generator 14b receives a high-state signal when the Tr oscillator 13a produces a higher frequency than the Tf oscillator 13b.

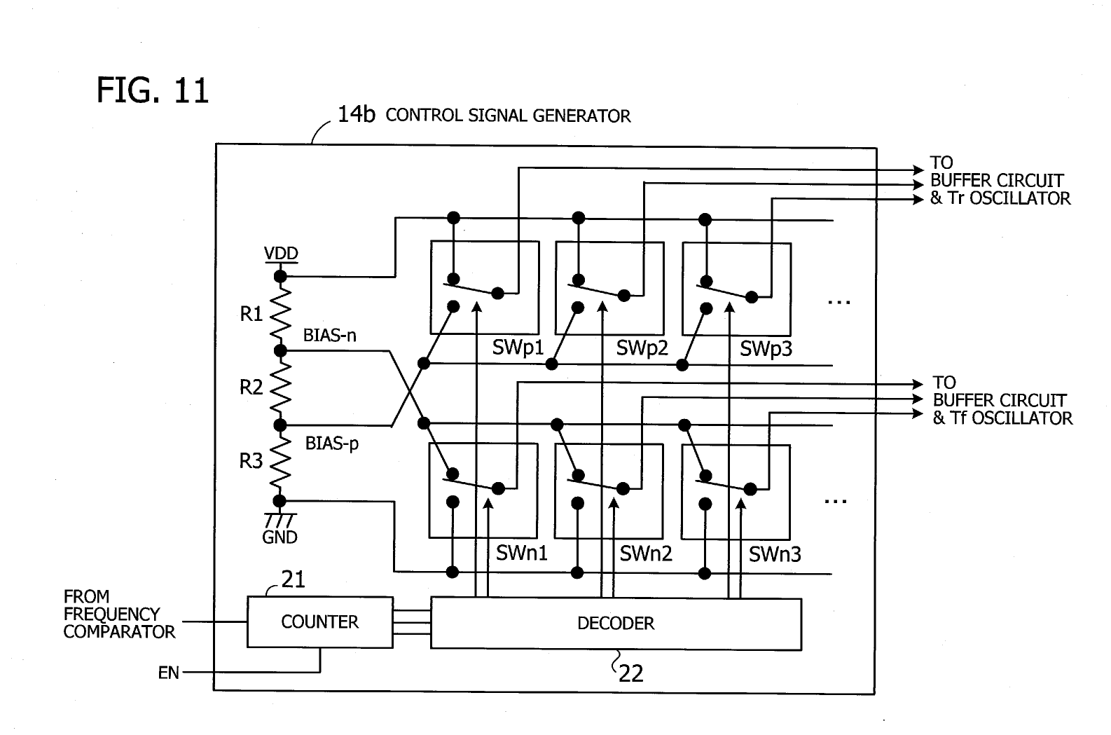

FIG. 11 is a schematic circuit diagram of the control signal generator 14b illustrated in FIG. 4. As seen in FIG. 11, this control signal generator 14b is formed from a counter 21, a decoder 22, resistors R1-R3, and switches SWp1-SWp3 and SWn1-SWn3.

The counter 21 is supplied with a signal indicating the result of frequency comparison that the frequency comparator 14a has made, as well as with an enable signal EN from some other source. The counter 21 accepts the comparison result signal from the frequency comparator 14a when the enable signal EN is active. The enable signal EN may be activated at appropriate intervals or on a demand basis under the control of, for example, a central processing unit (CPU) or other control device.

The counter 21 changes its count values with a step size of one, depending on the comparison result of the frequency comparator 14a. For example, the counter 21 increments itself by one when the Tr oscillator 13a is producing a higher frequency than the Tf oscillator 13b (i.e., the frequency comparator 14a outputs a high-state signal). The counter 21 decrements itself by one when the Tf oscillator 13b is producing a higher frequency than the Tr oscillator 13a (i.e., the frequency comparator 14a outputs a low-state signal).

The decoder 22 controls the state of each switch SWp1-SWp3 and SWn1-SWn3 according to count values supplied from the counter 21. Resistors R1-R3 divide the power supply voltage VDD to provide bias voltages Bias-p and Bias-n for the purpose of driving transistors M11-M18 in the buffer circuit 12 of FIG. 3. Inside the control signal generator 14b, the bias voltages Bias-p and Bias-p are wired to two groups of switches SWp1-SWp3 and SWn1-SWn3, respectively.

The switches SWp1-SWp3 select either the bias voltage Bias-p or power supply voltage VDD to drive transistors M11-M14 in the buffer circuit 12 and transistors M31-M33 in the Tr oscillator 13a. The switches SWn1-SWn3, on the other hand, select either the bias voltage Bias-n or ground voltage GND to drive transistors M15-M18 in the buffer circuit 12 and transistors M61-M63 in the Tf oscillator 13b.

As noted above, the counter 21 represents the current result of frequency comparison. For example, a count value greater than zero means that the Tr oscillator 13a is producing a higher frequency. This indicates that the buffer circuit 12 is producing a clock signal with a smaller Tr. On the other hand, when the count value is smaller than zero, it is the Tf oscillator 13b that is producing a higher frequency. This indicates a smaller Tf of the clock signal. With reference to those counter values, the decoder 22 operates to equalize Tr and Tf as follows. When Tr is found smaller than Tf, the decoder 22 controls switches SWp1-SWp3 and SWn1-SWn3 so as to increase Tr or decrease Tf. When Tf is found smaller than Tr, the decoder 22 controls switches SWp1-SWp3 and SWn1-SWn3 so as to increase Tf or decrease Tr.

While three switches SWp1-SWp3 are depicted in the upper half of FIG. 11, the control signal generator 14b actually contains as many such switches as the number of corresponding PMOS transistors in the buffer circuit 12 (e.g., four transistors M11-M14 in FIG. 3). This also applies to the switches SWn1-SWn3 seen in the lower half of FIG. 11. While FIG. 11 depicts three switches SWn1-SWn3, the control signal generator 14b actually contains as many such switches as the number of corresponding NMOS transistors in the buffer circuit 12 (e.g., four transistors M15-M18 in FIG. 3).

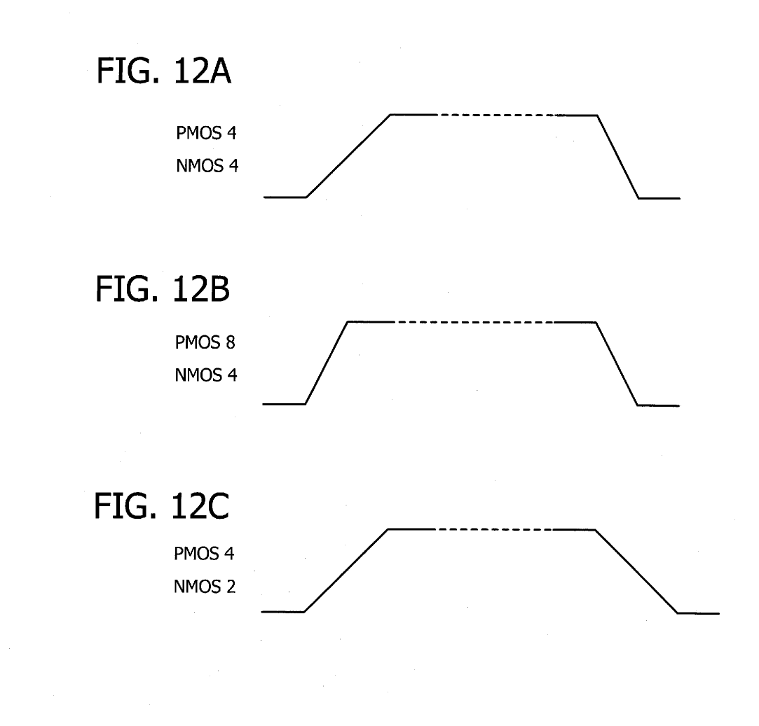

FIGS. 12A to 12C depict how the decoder 22 works in the circuit of FIG. 11. For example, FIGS. 12A to 12C illustrate waveforms of a clock signal provided by the buffer circuit 12 of FIG. 3 in several different situations. That is, the clock signal waveform may vary depending on how many of the PMOS transistors M11-M14 and NMOS transistors M15-M18 are turned on in the buffer circuit 12. The captions of FIGS. 12A to 12C indicate the numbers of active PMOS and NMOS transistors. Note that FIGS. 12A to 12C assume that the buffer circuit 12 contains eight PMOS transistors and eight NMOS transistors whose gates are connected to CONTROL SIGNALS, whereas FIG. 3 only depicts four PMOS transistors M11-M14 and four NMOS transistors M15-M18.

Referring to FIG. 12A, the clock signal has unequal Tr and Tf, the former being twice as long as the latter. It is assumed here that the decoder 22 turns on four PMOS transistors and four NMOS transistors in the buffer circuit 12. The illustrated Tr and Tf may be equalized in two ways. One way is to reduce Tr down to the point where Tr equals Tf as illustrated in FIG. 12B. Since the current Tr is twice as long as Tf in the present case, the equalization may be achieved by doubling the number of active PMOS transistors, from four to eight. The other way is to increase Tf up to the point where Tf equals Tr as illustrated in FIG. 12C. Since the current Tr is twice as long as Tf in the present case, the equalization may be achieved by reducing the number of active NMOS transistors in half, from four to two.

Which way of FIGS. 12B and 12C to choose depends on what applications the clock signal output circuit serves. The decoder 22 may also be configured to use both methods illustrated in FIGS. 12B and 12C. That is, the decoder 22 may change the number of active PMOS transistors, as well as the number of active NMOS transistors, so as to equalize Tr and Tf.

The number of control signal bits may be increased for more precise adjustment of Tr and Tf. For example, this is achieved by employing more switches in addition to SWp1-SWp3 and SWn1-SWn3 in the control signal generator 14b and adding more transistors to the buffer circuit 12, Tr oscillator 13a, and Tf oscillator 13b.

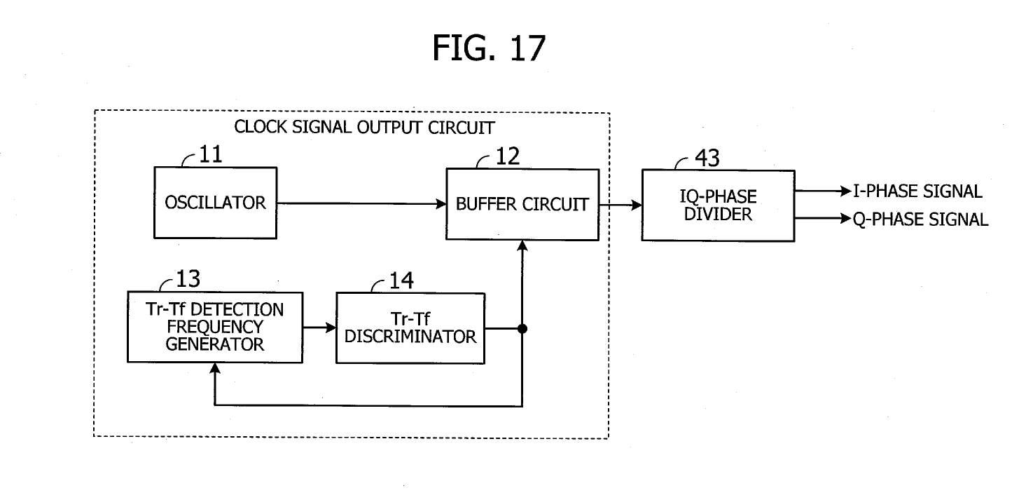

The proposed clock signal output circuit of FIG. 2 may be applied to a quadrature-phase clock circuit as will be exemplified later in FIGS. 17 and 18. Before discussing this application, the following section will discuss the case where a simple buffer circuit is used to output a clock signal.

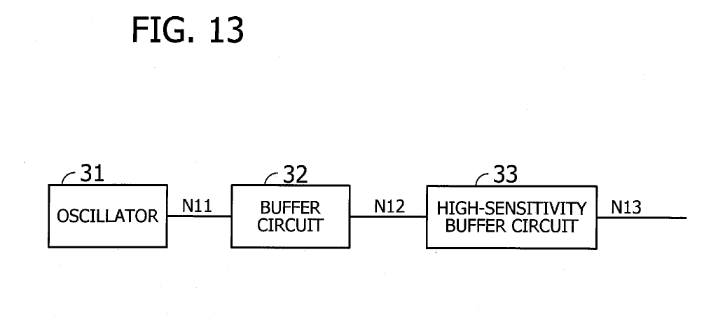

FIG. 13 illustrates an example circuit with a high-sensitivity buffer circuit added after a buffer circuit. The illustrated circuit includes an oscillator 31 to generate a clock signal, a buffer circuit 32 to provide an enhanced drive capability, and a high-sensitivity buffer circuit 33.

The oscillator 31 produces a clock signal with a duty ratio of 50%. The buffer circuit 32, on the other hand, has unequal Tr and Tf. The high-sensitivity buffer circuit 33 corrects this difference between Tr and Tf, thus outputting a clock signal with equalized Tr and Tf.

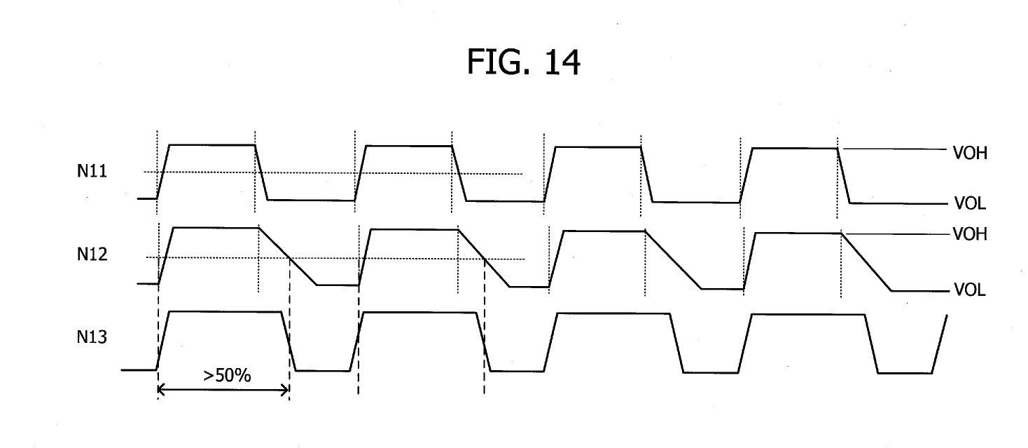

FIG. 14 illustrates output waveforms of the circuit of FIG. 13. For example, the three waveforms of FIG. 14 correspond to the voltages observed at nodes N11-N13 in the circuit of FIG. 13. As can be seen from N11 of FIG. 14, the oscillator 31 provides a clock signal with a duty cycle of 50% and balanced rise and fall times Tr and Tf. The subsequent buffer circuit 32, however, adds an extra fall time to the original Tf, thus producing a clock signal whose Tf is larger than Tr, as can be seen in N12 of FIG. 14. The high-sensitivity buffer circuit 33 corrects this difference between Tr and Tf as can be seen in N13 of FIG. 14.

The buffer circuit 32 expands Tf when it outputs the clock signal. This is viewed by the high-sensitivity buffer circuit 33 as an output duty ratio of over 50%. That is, the difference between Tr and Tf distorts the 50% duty ratio of the original clock signal, which may not be restored even if a high-sensitivity buffer circuit 33 is placed in the subsequent stage.

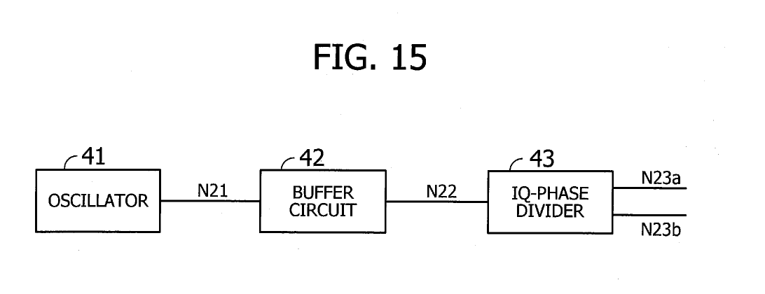

FIG. 15 illustrates an example circuit which provides a clock signal to an IQ-phase divider through a buffer circuit. The illustrated circuit includes an oscillator 41 to generate a clock signal, a buffer circuit to provide an enhanced drive capability, and an IQ-phase divider 43.

The oscillator 41 produces a clock signal with a duty ratio of 50%. The buffer circuit 42, on the other hand, has unequal Tr and Tf. The IQ-phase divider 43 divides this clock signal at the ratio of 2:1 to generate I-phase (in phase) and Q-phase (quadrature phase) clock signals with half the original frequency of the input clock signal.

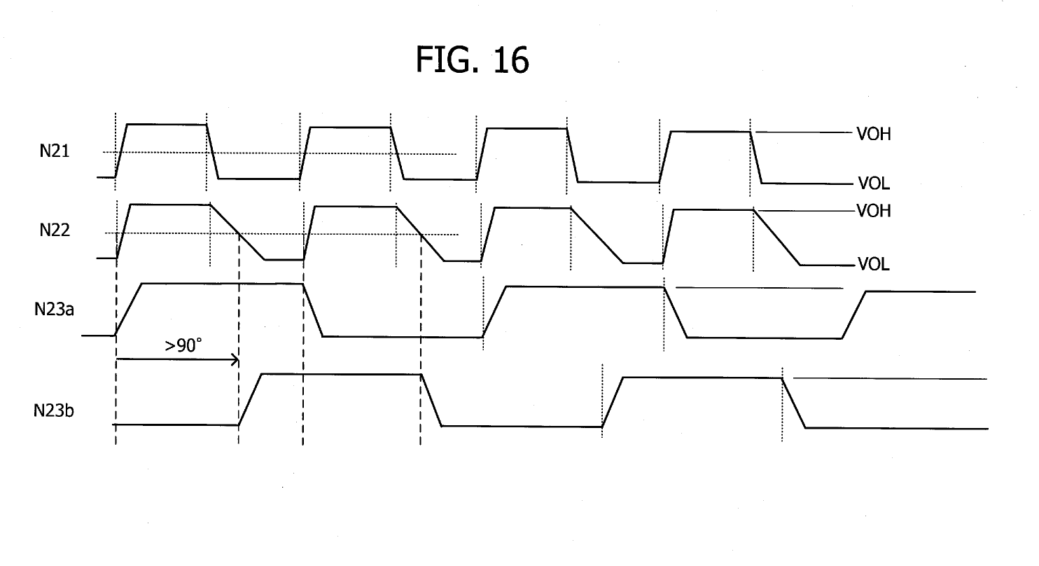

FIG. 16 illustrates output waveforms of the circuit of FIG. 15. For example, the four waveforms of FIG. 16 correspond to the voltages observed at nodes N21, N22, N23a, and N23b in the circuit of FIG. 15. As can be seen from N21 of FIG. 16, the oscillator 41 provides a clock signal with a duty cycle of 50% and balanced rise and fall times Tr and Tf. The subsequent buffer circuit 42, however, adds an extra fall time to the original Tf, thus producing a clock signal with unbalanced Tf and Tr (i.e., Tf>Tr) as can be seen in N22 of FIG. 16. Based on this clock signal from the buffer circuit 42, the IQ-phase divider 43 generates I-phase and Q-phase clock signals. As can be seen from N23a of FIG. 16, the I-phase clock signal switches between high and low in synchronization with the rising edges of the given clock signal at node N22. The Q-phase clock signal, on the other hand, switches between high and low in synchronization with the falling edges of the same clock signal.

Since the clock signal at node N22 has an extended Tf, the resulting Q-phase clock signal is delayed by more than 90 degrees relative to the I-phase clock signal. This means that the IQ-phase divider 43 fails to produce 90-degree out-of-phase clock signals. In other words, the difference between Tr and Tf in the clock signal output of the buffer circuit 42 hampers the IQ-phase divider 43 from producing the intended I-phase and Q-phase clock signals.

FIG. 17 illustrates an example circuit in which the clock signal output circuit of FIG. 2 is used together with an IQ-phase divider. The illustrated circuit is formed from an oscillator 11, a buffer circuit 12, a Tr-Tf detection frequency generator 13, a Tr-Tf discriminator 14, and an IQ-phase divider 43. The first four components come from the clock signal output circuit of FIG. 2, and the last component is what has been illustrated in FIG. 15.

The buffer circuit 12 in the clock signal output circuit provides a clock signal having equal Tr and Tf. The IQ-phase divider 43 produces I-phase and Q-phase clock signals with half the original frequency of the given clock signal. Because of the equalized Tr and Tf of the clock signal, the produced I-phase and Q-phase clock signals have a duty ratio of 50% and are 90 degrees out of phase with each other, thus enabling a subsequent mixer and other circuits (not illustrated) to operate correctly to remove image signals and achieve their purposes.

As can be seen from the above description, the proposed clock signal output circuit adjusts the rise time Tr and fall time Tf of a clock signal by converting them into frequency signals and comparing their frequencies, instead of using voltage-based techniques such as differentiation or threshold comparison. This circuit design offers accurate adjustment of Tr and Tf, thus enabling the buffer circuit to output a clock signal with equal rise and fall times.

The foregoing buffer circuit 12 (FIG. 3) contains PMOS transistors M1, M3, M5, and M7 and NMOS transistors M2, M4, M6, and M8 to drive a clock signal. Those transistors may be configured to have different current drivabilities, so that each transistor will have a different weight. This configuration of transistors enables fine-tuning of Tr and Tf. For example, transistors M3, M5, and M7 may respectively be configured to have two times, four times, and eight times as large current drivabilities as transistor M1. Similarly, transistors M4, M6, and M8 may respectively be configured to have two times, four times, and eight times as large current drivabilities as transistor M2.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention has(have) been described in detail, it should be understood that various changes, substitutions and alterations could be made hereto without departing from the spirit and scope of the invention.

What is claimed is:

1. A clock signal output circuit comprising:
a clock signal source which produces a clock signal;
a buffer circuit which drives the clock signal while adjusting rise and fall times of the clock signal according to control signals;
a rise-time frequency generator, responsive to the control signals, which produces a rise-time signal having a frequency corresponding to the rise time given by the buffer circuit;
a fall-time frequency generator, responsive to the control signals, which produces a fall-time signal having a frequency corresponding to the fall time given by the buffer circuit; and
a control signal generator which produces the control signals, based on the frequencies of the rise-time signal and fall-time signal.

2. The clock signal output circuit according to claim 1, wherein the buffer circuit comprises:
a plurality of high-state drive switches which drives the clock signal at a high state;
a plurality of low-state drive switches which drives the clock signal at a low state;
a high-state drive controller which controls connections between the high-state drive switches and a first voltage source according to the control signals; and
a low-state drive controller which controls connections between the low-state drive switches and a second voltage source according to the control signals.

3. The clock signal output circuit according to claim 2, wherein the rise-time frequency generator comprises:
a plurality of rise-time measurement switches which are equivalent to the high-state drive switches in characteristics;
a rise-time controller which controls connections between the rise-time measurement switches and the first voltage source according to the control signals; and
a rise-time integrator which integrates currents flowing through the rise-time measurement switches; and
a rise-time signal generator which produces the rise-time signal, based on the integration of currents at the rise-time integrator.

4. The clock signal output circuit according to claim 2, wherein the fall-time frequency generator comprises:
a plurality of fall-time measurement switches which are equivalent to the low-state drive switches in characteristics;
a fall-time controller which controls connections between the fall-time measurement switches and the second voltage source according to the control signals; and
a fall-time integrator which integrates currents flowing through the fall-time measurement switches; and
a fall-time signal generator which produces the fall-time signal, based on the integration of currents at the fall-time integrator.

5. The clock signal output circuit according to claim 2, wherein the control signal generator provides the control signals to the high-state drive controller and low-state drive controller so as to equalize the frequencies of the rise-time signal and fall-time signal.

6. The clock signal output circuit according to claim 2, wherein the high-state drive switches and low-state drive switches have different current drivabilities.

7. The clock signal output circuit according to claim 2, wherein the high-state drive switches and low-state drive switches each comprise a transistor.

8. The clock signal output circuit according to claim 3, wherein the rise-time measurement switches each comprise a transistor.

9. The clock signal output circuit according to claim 4, wherein the fall-time measurement switches each comprise a transistor.
